(19) United States
(12) Patent Application Publication
(10) Pub. No.: US 2014/0000681 A1
(43) Pub. Date: Jan. 2, 2014

(54) PHOTOVOLTAIC MODULE BACK-SHEET AND PROCESS OF MANUFACTURE

(71) Applicant: E I DU PONT DE NEMOURS AND COMPANY, Wilmington, DE (US)

(72) Inventors: CHEN QIAN ZHAO, Newark, DE (US); Scott B. Marks, Newark, DE (US); Jonathan Aaron Karas, Solon, OH (US)

(73) Assignee: E I DU PONT DE NEMOURS AND COMPANY, Wilmington, DE (US)

(21) Appl. No.: 13/793,586

(22) Filed: Mar. 11, 2013

Related U.S. Application Data
(60) Provisional application No. 61/664,872, filed on Jun. 27, 2012.

(51) Int. Cl. H01L 31/048

(52) U.S. Cl. CPC H01L 31/0487
USPC 136/251; 427/398.1; 438/66

(57) ABSTRACT

A back-sheet for a photovoltaic module is provided. A process for forming a back-sheet for a photovoltaic module includes the steps of providing a fluoropolymer film, providing a polymer melt comprising 20 to 95 weight percent ethylene propylene diene terpolymer, 5 to 70 weight percent of inorganic particulates, and 0 to 50 weight percent of adhesive selected from thermoplastic polymer adhesives and tackifiers, and depositing the polymer melt directly on the fluoropolymer film and pressing the fluoropolymer film and polymer melt together and cooling the polymer melt to form a first polymer layer adhered to the fluoropolymer film.

### BACKGROUND OF THE INVENTION

1. Field of the Disclosure

The present invention relates to durable protective films and sheets for photovoltaic modules, and more particularly to the use in photovoltaic modules of ethylene propylene diene terpolymer films or sheets. The invention more particularly relates to a process for manufacturing a back-sheet for photovoltaic modules in which a layer of an ethylene propylene diene terpolymer melt is deposited directly on and adhered to a fluorinated polymer layer, and to a process for adhering such back-sheet directly to the back side of photovoltaic cells.

2. Description of the Related Art

A photovoltaic module (also know as a solar cell module) refers to a photovoltaic device for generating electricity directly from light, particularly, from sunlight. Typically, an array of individual solar cells is electrically interconnected and assembled in a module, and an array of modules is electrically interconnected together in a single installation to provide a desired amount of electricity. If the light absorbing semiconductor material in each cell, and the electrical components used to transfer the electrical energy produced by the cells, can be suitably protected from the environment, photovoltaic modules can last 20, 30, and even 40 or more years without significant degradation in performance.

As shown in FIG. 1, a photovoltaic module 10 is shown in cross section with a light-transmitting substrate 12 or front sheet, an encapsulant layer 14, an active photovoltaic cell layer 16, another encapsulant layer 18 and a protective back-sheet 20. The light-transmitting front sheet substrate, also known as the incident layer, is typically glass or a durable light-transmitting polymer film. The encapsulant layers 14 and 18 adhere the photovoltaic cell layer 16 to the front and back sheets, they seal and protect the photovoltaic cells from moisture and air, and they protect the photovoltaic cells against mechanical impacts such as hail. The encapsulant layers 14 and 18 are typically comprised of a thermoplastic or thermosetting resin such as ethylene-vinyl acetate copolymer (EVA). The photovoltaic cell layer 16 may be any type of solar cell that converts sunlight to electric current such as single crystal silicon solar cells, polycrystalline silicon solar cells, microcrystalline silicon solar cells, amorphous silicon-based solar cells, copper indium (gallium) diselenide solar cells, cadmium telluride solar cells, compound semiconductor solar cells, dye sensitized solar cells, and the like. The back-sheet 20 provides structural support for the module 10, it electrically insulates the module, and it helps to protect the module wiring and other components against the elements, including heat, water vapor, oxygen and UV radiation. The back-sheet needs to remain intact and adhered to the rest of the module for the service life of the photovoltaic module, which may extend for multiple decades.

Multilayer laminates have been employed as photovoltaic module back-sheets. One or more of the laminate layers in such back-sheets conventionally comprise a highly durable and long lasting polyvinyl fluoride (PVF) film which is available from E. I. du Pont de Nemours and Company as Tedlar® film. PVF films resist degradation by sunlight and they provide a good moisture barrier properties over long periods of time. PVF films are typically laminated to other polymer films that contribute mechanical and dielectric strength to the back-sheet, such as polyester films, as for example polyethylene terephthalate (PET) films. Back-sheets of PVF/PET or of PVF/PET/PVF are adhered to the encapsulant layer on the back side of the solar cells.

There is a need for a photovoltaic module back-sheet that is durable over extended periods of time, that can adhere directly to the back surface of solar cells so as to seal and protect the solar cells, and that offers excellent moisture resistance and good electrical insulation properties. There is a further need for such photovoltaic module back-sheets that are economical to produce and use.

### SUMMARY

The invention provides a process for forming a back-sheet for a photovoltaic module. The disclosed process includes the steps of:

providing a fluoropolymer film;

providing a polymer melt comprising 20 to 95 weight percent ethylene propylene diene terpolymer, 5 to 70 weight percent of inorganic particulates, and 0 to 50 weight percent of adhesive selected from thermoplastic polymer adhesives and tackifiers, based on the weight of the polymer melt;

depositing the polymer melt directly on the fluoropolymer film and pressing the fluoropolymer film and polymer melt together and cooling the polymer melt to form a first polymer layer from the polymer melt, the first polymer layer having a thickness of at least 0.1 mm, wherein the peel strength between said fluoropolymer film and the first polymer layer is greater than 2 Newtons/cm after 1000 hours of exposure at 85° C. and 85% relative humidity.

In one preferred embodiment, the first polymer layer comprises 25 to 90 weight percent ethylene propylene diene terpolymer, 5 to 70 weight percent of inorganic particulates, and 5 to 35 weight percent of adhesive selected from thermoplastic polymer adhesives and rosin based tackifiers. In another preferred embodiment, the first polymer layer comprises 10 to 70 weight percent of inorganic particulates selected from silica and silicates and having an average particle diameter between and including any two of the following diameters: 0.1, 0.2, 15, 45, and 100 microns.

The polymer melt may be deposited on the fluoropolymer film by extruding the polymer melt as a layer directly onto the fluoropolymer film. Alternatively, the polymer melt may be formed between heated calendar rolls and deposited onto the fluoropolymer film and passed through a nip to form a polymer layer adhered to said fluoropolymer film. The polymer layer preferably has a thickness of at least 0.25 mm.

A photovoltaic module is also disclosed having a plurality of solar cells with a front light receiving side and an opposite rear side. A polymer layer has opposite first and second sides with the first side of the polymer layer adhered directly to the rear side of said plurality of solar cells. The polymer layer comprises 20 to 95 weight percent ethylene propylene diene terpolymer, 5 to 70 weight percent of inorganic particulates, and 0 to 50 weight percent of adhesive selected from thermoplastic polymer adhesives and tackifiers, based on the weight of the polymer layer. A fluoropolymer film is adhered directly to the second side of the polymer layer. The peel strength between the fluoropolymer film and the polymer layer is preferably greater than 8 Newtons/cm after 1000 hours of exposure at 85° C. and 85% relative humidity.

In one preferred embodiment, the polymer layer comprises 25 to 90 weight percent ethylene propylene diene terpolymer, 5 to 70 weight percent of inorganic particulates, and 5 to 35 weight percent of adhesive selected from thermoplastic polymer adhesives and rosin based tackifiers, based on the weight of the polymer layer. The polymer layer may comprise 10 to 70 weight percent of inorganic particulates selected from silica and silicates and having an average particle diameter between and including any two of the following diameters: 0.1, 0.2, 15, 45, and 100 microns. The inorganic particulates are preferably selected from the group of calcium carbonate, titanium dioxide, kaolin and clays, alumina trihydrate, talc, silica, antimony oxide, magnesium hydroxide, barium sulfate, mica, vermiculite, alumina, titania, wollastinite, boron nitride, and combinations thereof. The polymer layer preferably has a thickness in the range of 0.25 to 0.75 mm.

### BRIEF DESCRIPTION OF THE DRAWINGS

The detailed description will refer to the following drawings, wherein like numerals refer to like elements:

FIG. 1 is a cross-sectional view of a conventional photovoltaic module;

FIG. 2 is a schematic view of a process for producing a back-sheet according to one disclosed process;

FIG. 3 is a schematic view of a process for producing a back-sheet according to another disclosed process;

FIG. 4 is a schematic view of a process for producing a back-sheet according to another disclosed process;

FIG. 5 is a cross-sectional view of a photovoltaic module with a disclosed back-sheet.

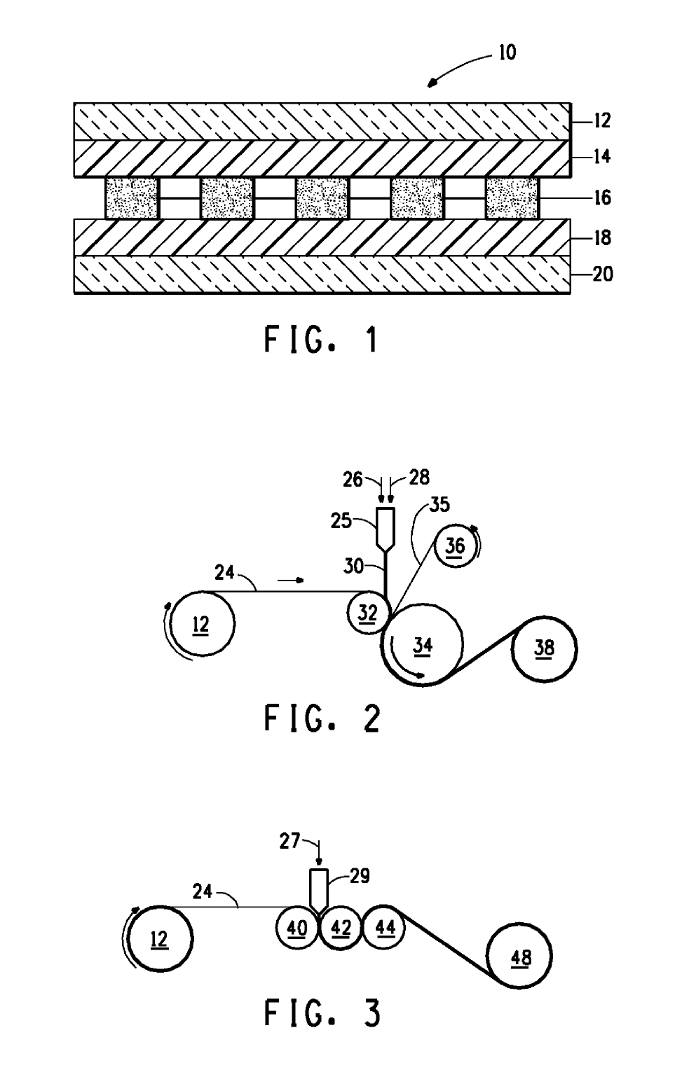

### DETAILED DESCRIPTION

To the extent permitted by the United States law, all publications, patent applications, patents, and other references mentioned herein are incorporated by reference in their entirety.

The materials, methods, and examples herein are illustrative only and the scope of the present invention should be judged only by the claims.

### DEFINITIONS

The following definitions are used herein to further define and describe the disclosure.

The terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

The terms “sheet”, “layer” and “film” are used in their broad sense interchangeably. A “back-sheet” is a sheet, layer or film on the side of a photovoltaic module that faces away from a light source, and is generally opaque.

“Encapsulant” means material are used to encase the fragile voltage-generating solar cell layer to protect it from environmental or physical damage and hold it in place in the photovoltaic module.

Encapsulant layers are typically positioned between the solar cell layer and the incident front sheet layer, and between the solar cell layer and the back-sheet backing layer. Suitable polymer materials for these encapsulant layers typically possess a combination of characteristics such as high transparency, high impact resistance, high penetration resistance, high moisture resistance, good ultraviolet (UV) light resistance, good long term thermal stability, adequate adhesion strength to front-sheets, back-sheets, other rigid polymeric sheets and solar cell surfaces, and long term weatherability.

The term “copolymer” is used herein to refer to polymers containing copolymerized units of two different monomers (a dipolymer), or more than two different monomers.

Durable substrates for use as back-sheets in photovoltaic modules are disclosed. Photovoltaic modules made with such durable substrates as the module back-sheet are also disclosed. Also disclosed are processes for making such durable substrates for use in photovoltaic modules, and process for making photovoltaic modules with the durable substrates as the back-sheet. The durable substrate is a layer of an ethylene propylene diene terpolymer adhered directly to a thermoplastic fluoropolymer film, such as polyvinyl fluoride (PVF) homopolymer or copolymer film or polyvinylidene (PVDF) homopolymer or copolymer film.

The disclosed integrated back-sheet comprises an electrically insulating polymer substrate comprised of an ethylene propylene diene terpolymer (“EPDM”). EPDM is an ethylene-propylene elastomer with a chemically saturated, stable polymer backbone comprised of ethylene and propylene monomers combined in a random manner. A non-conjugated diene monomer is terpolymerized in a controlled manner on the ethylene-propylene backbone to provide reactive unsaturation in a side chain that is available for vulcanization. Two of the most widely used diene termonomers for making EPDM are ethylidene norbornene and dicyclopentadiene. Different dienes incorporate with different tendancies for introducing long chain branching or polymer side chains that influence processing and rates of vulcanization by sulfur or peroxide cures. Specialized catalysts are used to polymerize the monomers including Aeigler-Natta catalysts and metallocene catalysts. Particularly useful EPDM terpolymers are comprised of 40 to 90 mole percent ethylene monomer units, 2 to 60 mole percent propylene monomer units, and 0.5 to 8 mole percent diene monomer units. Specific examples of these EPDM terpolymers include ethylene propylene norbornadiene terpolymer and ethylene propylene dicyclopentadiene terpolymer. EPDM terpolymers are commercially available from DSM Elastomers, Dow Chemical Company, Mitsui Chemicals, and Sumitomo Chemical Company, among others. The EPDM polymers preferably have Mooney viscosity of 15 to 85 at 125° C., tested according to ASTM D 1646.

The EPDM-containing substrate further comprises 5% to 70% by weight of inorganic particulates, and more preferably 10% to 65% of inorganic particulates, and even more preferably 25% to 65% of inorganic particulates. The inorganic particulates preferably comprise amorphous silica or silicates such as crystallized mineral silicates. Preferred silicates include clay, kaolin, wollastinite, vermiculite, mica and talc (magnesium silicate hydroxide). Other useful inorganic particulate materials include calcium carbonate, alumina trihydrate, antimony oxide, magnesium hydroxide, barium sulfate, alumina, titania, titanium dioxide, zinc oxide and boron nitride. Preferred inorganic particulate materials have an average particle diameter less than 100 microns, and preferably less than 45 microns, and more preferably less than 15 microns. If the particle size is too large, defects, voids, pin holes, and surface roughness of the film may be a problem. If the particle size is too small, the particles may be difficult to disperse and the viscosity may be excessively high. Average particle diameters of the inorganic particulates are preferably between and including any two of the following diameters: 0.1, 0.2, 1, 15, 45 and 100 microns. More preferably, the particle diameter of more than 99% of the inorganic particulates is between 0.1 and 100 microns, and more preferably between 0.1 and 45 microns, and even more preferably between about 0.2 and 15 microns.

The inorganic particulate material adds reinforcement and mechanical strength to the sheet and it reduces sheet shrinkage and curl. Platelet shaped particulates such as mica and talc and/or fibrous particles provide especially good reinforcement. The inorganic particulates also improve heat dissipation from the solar cells to which the integrated back-sheet is attached which reduces the occurrence of hot spots in the solar cells. The presence of the inorganic particulates also improves the fire resistance of the back-sheet. The inorganic particulates also contribute to the electrical insulation properties of the back-sheet. The inorganic particulates may also be selected to increase light refractivity of the back-sheet which serves to increase solar module efficiency and increase the UV resistance of the back-sheet. Inorganic particulate pigments such as titanium dioxide serve to make the sheet whiter, more opaque and more reflective which is often desirable in a photovoltaic module back-sheet layer. The presence of the inorganic particulates can also serve to reduce the overall cost of the EPDM-containing substrate.

In one preferred embodiment, an EPDM-containing photovoltaic module substrate layer is comprised of an EPDM terpolymer combined inorganic particulates and one or more tackifiers or thermoplastic polymer adhesives. EPDM, inorganic particulates, and tackifiers or thermoplastic polymer adhesives may be mixed by known compounding processes. In one aspect, the EPDM-containing substrate comprises 20 to 95% by weight of EPDM, 5 to 70% by weight of inorganic particulate material, and 1 to 50% by weight of one or more of tackifiers and thermoplastic polymer adhesives, and more preferably and 5 to 30% by weight of one or more of tackifiers and thermoplastic polymer adhesives, and even more preferably and 10 to 30% by weight of one or more of tackifiers and thermoplastic polymer adhesives. The tackifiers and/or thermoplastic polymer adhesives serve to improve the adhesion of the EPDM-containing substrate to the fluoropolymer outer layer such as a PVF or PVDF film. The thermoplastic adhesive or the tackifier may also serve to improve the adhesion of the back-sheet to the back of the solar cells when the EPDM layer of the back-sheet is adhered to the back of the solar cells.

A preferred thermoplastic adhesive is a polyolefin plastomer such as a non-aromatic ethylene-based copolymer adhesive plastomer of low molecular weight with a melt flow index of greater than 250. Such polyolefin adhesive materials are highly compatible with the EPDM, they have low crystallinity, they are non-corrosive, and they provide good adhesion to fluoropolymer films. A preferred polyolefin plastomer is Affinity™ GA 1950 polyolefin plastomer obtained from Dow Chemical Company of Midland, Mich. Other thermoplastic polymer adhesives useful in the disclosed olefin-based elastomer containing back-sheet substrate include ethylene copolymer adhesives such as ethylene acrylic acid copolymers and ethylene acrylate and methacrylate copolymers. Ethylene copolymer adhesives that may be used as the thermoplastic adhesive include copolymers comprised of at least 50 wt % ethylene monomer units, copolymerized in one or more of the following: ethylene-C₁₋₄ alkyl methacrylate copolymers and ethylene-C₁₋₄ alkyl acrylate copolymers; ethylene-methacrylic acid copolymers, ethylene-acrylic acid copolymers, and blends thereof; ethylene-maleic anhydride copolymers; polybasic polymers formed of ethylene monomer units with at least two co-monomers selected from C₁₋₄ alkyl methacrylate, C₁₋₄ alkyl acrylate, ethylene-methacrylic acid, ethylene-acrylic acid and ethylene-maleic anhydride; copolymers formed by ethylene and glycidyl methacrylate with at least one co-monomer selected from C₁₋₄ alkyl methacrylate, C₁₋₄ alkyl acrylate, ethylene-methacrylic acid, ethylene-acrylic acid, and ethylene-maleic anhydride; and blends of two or more of these ethylene copolymers. Another thermoplastic adhesive useful in the EPDM containing substrate layer of the disclosed integrated back-sheet is an acrylic hot melt adhesive. Such an acrylic hot melt adhesive may serve as the thermoplastic adhesive on its own or in conjunction with an ethylene copolymer adhesive to improve the adhesion of the EPDM containing layer of the back-sheet to the fluoropolymer film. One preferred acrylic hot melt adhesive is Euromelt 707 US synthetic hot melt adhesive from Henkel Corporation of Dusseldorf, Germany. Other thermoplastic adhesives that may be utilized in the olefin-based elastomer substrate layer include polyurethanes, synthetic rubber, and other synthetic polymer adhesives.

Preferred tackifiers useful in the disclosed EPDM containing back-sheet substrate include hydrogenated rosin-based tackifiers, acrylic low molecular weight tackifiers, synthetic rubber tackifiers, hydrogenated polyolefin tackifiers such as polyterpene, and hydrogenated aromatic hydrocarbon tackifiers. Two preferred hydrogenated rosin-based tackifiers include FloraRez 485 glycerol ester hydrogenated rosin tackifier from Florachem Corporation and Stabelite Ester-E hydrogenated rosin-based tackifier from Eastman Chemical.

Other thermoplastic adhesives that may be utilized in the EPDM-containing back-sheet substrate includes polyurethanes, acrylic hot melt adhesives, synthetic rubber, and other synthetic polymer adhesives.

The EPDM-containing substrate may further comprise additives including, but are not limited to, plasticizers such as polyethylene glycol, processing aides, flow enhancing additives, lubricants, dyes, flame retardants, impact modifiers, nucleating agents to increase crystallinity, antiblocking agents such as silica, thermal stabilizers, hindered amine light stabilizers (HALS), UV absorbers, UV stabilizers, antioxidants, dispersants, surfactants, primers, and reinforcement additives, such as glass fiber and the like. Compounds that help to catalyze cross-linking reactions in EPDM such as peroxides and silanes may also be used. Such additives typically are added in amounts of less than 3% by weight of a EPDM containing substrate with the total of such additional additives comprising less than 10% by weight of the EPDM containing substrate and more preferably less than 5% by weight of the EPDM containing substrate.

The EPDM, the inorganic particulates, and the thermoplastic adhesive or tackifier may be compounded and mixed by methods known in the art. This mixture is melted and melt deposited as a layer directly on a fluoropolymer film. When the integrated back-sheet is applied to a module, the fluoropolymer film layer will be on the side of the EPDM containing layer that is opposite from the solar cell layer. The EPDM containing layer adheres directly to the fluoropolymer film without the need for an additional adhesive layer.

As used herein “fluoropolymer” means homopolymers and copolymers of fluorinated monomer units and copolymers of fluorinated monomers and non-fluorinated monomers in which the fluorinated monomer units in the copolymer account for 40 to 99% by weight of the copolymer. The fluoropolymer film may, for example, be comprised of polyvinyl fluoride, polyvinylidene fluoride, polytetrafluoroethylene, poly chloro trifluoroethylene, ethylene-tetrafluoroethylene copolymers, tetrafluoroethylene/hexafluoropropylene/vinylidene fluoride terpolymer (THV), copolymers and terpolymers comprising polyvinyl fluoride and polytetrafluoroethylene, and the like. Preferred fluoropolymer films include PVF homopolymer or copolymer film or PVDF homopolymer or copolymer film. Suitable PVF films are more fully disclosed in U.S. Pat. No. 6,632,518.

The thickness of the fluoropolymer film layer is not critical and may be varied depending on the particular application. Generally, the thickness of the fluoropolymer film will range from about 0.1 to about 10 mils (about 0.003 to about 0.26 mm), and more preferably within the range of about 1 mil (0.025 mm) to about 4 mils (0.1 mm). Alternatively, the fluoropolymer film may be a layer of a laminate in which a fluoropolymer film layer is laminated to another polymer film such as a polyester film. In another embodiment, the fluoropolymer film layer can be a fluoropolymer coated polymer substrate such as a fluoropolymer coated polyester substrate. Examples of suitable fluoropolymer coated polymer substrates included PVDF and PVF fluoropolymer coated polyester substrates as fully disclosed in U.S. Pat. No. 7,553,540.

One process for forming the disclosed solar panel back-sheet material is illustrated in FIG. 2. A fluoropolymer film 24 is fed from a roll 12 to an extrusion coating station comprising a single screw or twin screw extruder and an extrusion die. An EPDM-containing melt layer 30 is extruded from an extruder die 25. The extruded EPDM-containing layer 30 may be comprised of a single EPDM-containing layer or of multiple co-extruded layers where each layer is designed to perform a specific function. For example, and as shown in FIG. 2, one or more different EPDM-containing feeds 26 and/or 28 are fed to the extruder where the feed 26 forms an EPDM-containing melt layer formulated to adhere to the fluoropolymer film, and where the feed 28 forms a distinct EPDM-containing sub-layer with properties that will allow it to adhere well to the back of a photovoltaic module when the back-sheet laminate is adhered directly to the back side of solar cells. For example, a tackifier or a thermoplastic polymer adhesive, such as a functionalized ethylene copolymer, can be added to one or more of the layers to make them adhere well to the fluoropolymer film layer or to the back of the solar cell. It is contemplated that the extruded EPDM-containing layer 30 could be made with additional sub-layers that serve other functions such as joining the other sub-layers together or providing desired moisture barrier or insulating properties.

The EPDM-containing material is melted in the extruder and extruded through a slit die to form a melt layer 30 that is extrusion coated directly onto the surface of the fluoropolymer film 24. The opening of the die is preferably spaced about 10 to 500 mm from the surface of the fluoropolymer film. The die thickness, the melt extrusion rate and the line speed of the fluoropolymer film are adjusted to obtain an EPDM-containing layer coating with a thickness of about 0.1 to 1.3 mm, and more preferably with a thickness of about 0.25 to 0.80 mm. The coated film is passed through a nip formed between the rolls 32 and 34. The rolls 32 and 34 are lamination rollers as known in the art, and may have hard or flexible surfaces, and may be heated or cooled depending on the desired processing conditions. The temperature of the rolls 32 and 34 are preferably in the range of 50° to 200° F., and more preferably 60° to 90° F. The roll surfaces may have a gloss or matte finishes. The pressure in the nip formed between the rolls 32 and 34 is preferably in the range of about 30 to 90 psi (207 to 621 kPa). An optional release layer 35, such as a Mylar® polyester film, wax release paper, or silicon release sheet may be fed into the nip between the EPDM-containing layer and the lamination roll 34. The EPDM-containing layer on the fluoropolymer film, with the optional release film 35, is collected on a collection roll 38 after coming off the lamination roller 34.

An alternative sheet extrusion process is schematically illustrated in FIG. 3. The EPDM-containing material 27 is melted in the extruder 29 and extruded through a slit die directly into a nip formed between the rolls 40 and 42. A fluoropolymer film 24 is also fed into the nip from a roll 12. The EPDM-containing melt is formed into a sheet layer by the nip between the roll 40 and 42 and by the nip between the roll 42 and the roll 44 to which the EPDM-containing layer and the fluoropolymer film are transferred. The sheeting rolls 40, 42 and 44 form the EPDM-containing layer into a uniformly thick layer adhered to the fluoropolymer film 24. The opening of the die is preferably spaced about 10 to 500 mm from the nip between the rolls 40 and 42. The die thickness, the melt extrusion rate, the line speed, and the nip opening are adjusted to obtain an EPDM-containing layer coating with a thickness of about 0.1 to 1.3 mm, and more preferably with a thickness of about 0.25 to 0.80 mm. The rolls 40, 42 and 44 are quench/nip rolls as known in the art, and may have hard or flexible surfaces, and may be heated or cooled depending on the desired processing conditions. The temperature of the rolls 32 and 34 are preferably in the range of 50° to 200° F., and more preferably 60° to 90° F. The roll surface may have a gloss or matte finish. The nip pressure is preferably in the range of 30 to 90 psi (207 to 621 kPa). The EPDM/fluoropolymer film laminate is collected on a take-up roll 48. In an alternative embodiment, a release sheet (not shown), as described above with regard to the release sheet 35, is applied over the free surface of the EPDM-containing layer before the EPDM/fluoropolymer film laminate is collected on the collection roll 48.

Another alternative process for forming an EPDM/fluoropolymer film back-sheet laminate is schematically shown in FIG. 4. The EPDM, inorganic particles and any tackifier or thermoplastic adhesive are mixed in a compounder such a screw compounding machine. The compounded EPDM-containing mixture is pelletized into pellets 55 and fed into a mixer 54. The pellets are discharged from the mixer 54 as a pellet stream 56 to a melt zone 58 formed between the heated calendar rolls 50 and 52. Preferably the calendar rolls have a chrome plated surface, and are heated to a surface temperature in the range of 140 to 200° C., and more preferably 160 to 180° C. The calendar rolls typically have a diameter of form 20 to 60 cm and a length of from 15 cm to 2 m. The calendar rolls 50 and 52 are spaced from each other by about 0.15 to 1.2 mm, and more preferably by about 0.3 to 0.8 mm, depending upon the desired EPDM layer thickness. A molten film 58 of the melted EPDM-containing polymer is carried on the surface of the heated calendar roll 50 as shown in FIG. 4. The molten film 58 transfers to an adjoining roll 60 located below the calendar roll 50 and that is rotating in the same direction as the calendar roll 50. The roll 60 has a diameter and length similar to the calendar roll 50, but may be larger or smaller. Roll 60 preferably has a chrome plated surface, and is heated to a surface temperature in the range of 100 to 160° C., and more preferably 110 to 150° C.

A fluoropolymer film 24 is fed from a supply roll 12 to a nip formed between the roll 60 and a roll 61. The roll 61 presses the fluoropolymer film into contact with the EPDM-containing material on the surface of the heated calendar roll 60 such that the EPDM-containing material is transferred to the fluoropolymer film. The roll 61 has a diameter and length that is similar to the diameter and length of the roll 60, but may be larger or smaller. The roll 61 preferably has a chrome plated surface with a surface speed that is substantially the same as the surface speed of the roll 60 and the calendar roll 50. The roll 61 is preferably heated to a surface temperature in the range of 100 to 160° C., and more preferably 110 to 150° C. The EPDM/fluoropolymer film laminate is carried by the transfer rollers 62 to a collection roll 68. In one embodiment (not shown), a release sheet, like the release sheet 35 described above, is applied over the free surface of the EPDM-containing layer before the EPDM/fluoropolymer film is collected on the collection roll 68.

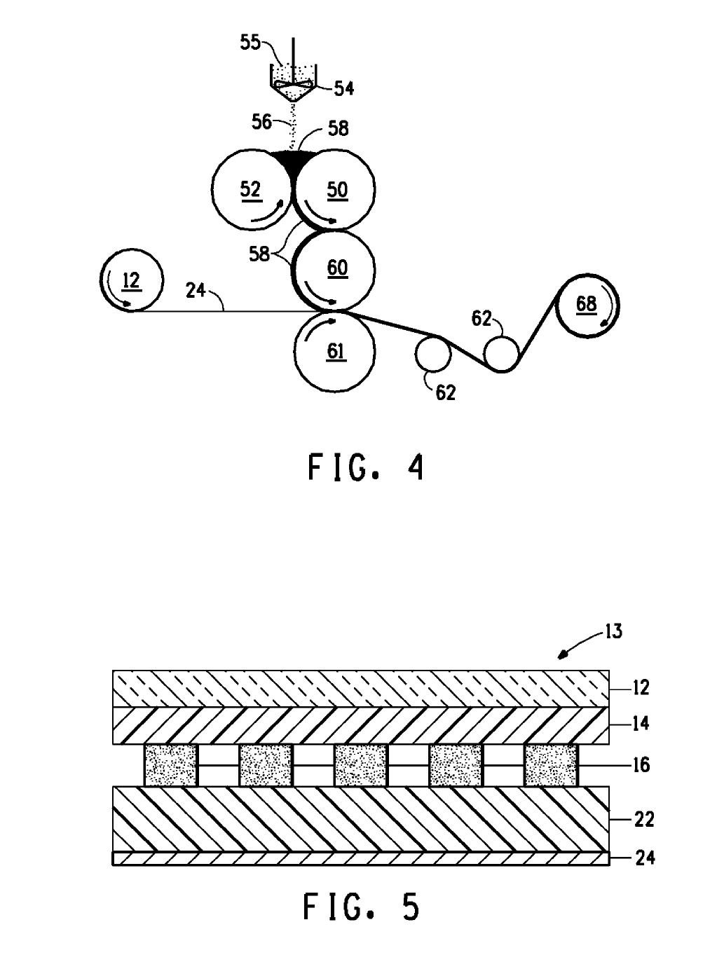

The EPDM-containing material forms a layer 22 directly on the fluoropolymer film 24 as can be seen in the photovoltaic module cross-sectional view of FIG. 5. The EPDM-containing layer preferably has a thickness in the range of 0.1 to 1.3 mm, and more preferably between 0.25 to 0.80 mm. It is important that the EPDM-containing layer not delaminate from the fluoropolymer film, even after extended exposure to heat and humidity. The peel strength between the fluoropolymer film and the EPDM-containing layer, after 1000 hours of exposure to damp heat (85° C. at 85% relative humidity) is preferably at least 2 Newtons/cm, and more preferably at least 8 Newtons/cm, when tested according to ASTM D3167.

The side of the EPDM-containing layer surface opposite to the side on which the EPDM-containing layer is adhered to the fluoropolymer film adheres directly to the back side of the solar cell layer and no other encapsulant layer is used on the back side of the solar cell. The EPDM-containing layer serves the functions of both a back-sheet and an encapsulant layer on the back side of the solar cell. A separate conventional encapsulant layer is still used on the front side of the solar cell. FIG. 5 shows a cross-sectional view of an EPDM-containing sheet 22 adhered directly to the rear side of the solar cell layer 16. A light transmitting front sheet 12 is adhered to a front encapsulant layer 14 on the front side of the solar cell layer 16. The front sheet 12 is typically a glass or transparent polymer sheet and the encapsulant layer 14 may be a conventional encapsulant such as ethylene vinyl acetate copolymer. The EPDM-containing sheet 22 serves as both the rear encapsulant layer and as a portion of the back-sheet of the photovoltaic module. The edges of solar module 13 between the front encapsulant layer 14 and the EPDM-containing layer 22 can be sealed with a conventional edge seal such as a polybutyl rubber edge seal material.

In another embodiment, the photovoltaic module with an EPDM-containing substrate may have one or more metal layers incorporated into the EPDM containing layer. The metal layer(s) can be a thin metal foil such as an aluminum, copper or nickel foil, a plated metal layer, a sputtered metal layer or a metal layer deposited by other mean such as chemical solution deposition. Preferred metal layers include metal foils, metal oxide layers and sputtered metal layers. Such metal layers provide increased resistance to moisture ingress. Metal layers may also be patterned on the EPDM containing layer as circuits for electrical connection to the back contacts of back-contact solar cells.

The photovoltaic cell layer (also know as the active layer) of the module is made of an ever increasing variety of materials. Within the present invention, a solar cell layer 16 is meant to include any article which can convert light into electrical energy. Typical art examples of the various forms of solar cells include, for example, single crystal silicon solar cells, polycrystal silicon solar cells, microcrystalline silicon solar cells, amorphous silicon based solar cells, copper indium (gallium) diselenide solar cells, cadmium telluride solar cells, compound semiconductor solar cells, dye sensitized solar cells, and the like. The most common types of solar cells include multi-crystalline solar cells, thin film solar cells, compound semiconductor solar cells and amorphous silicon solar cells due to relatively low cost manufacturing ease for large scale solar modules.

The front encapsulant layer 14 of the photovoltaic module is typically comprised of ethylene methacrylic acid and ethylene acrylic acid, ionomers derived therefrom, or combinations thereof. Such encapsulant layers may also be films or sheets comprising poly(vinyl butyral) (PVB), ethylene vinyl acetate (EVA), poly(vinyl acetal), polyurethane (PU), linear low density polyethylene, polyolefin block elastomers, ethylene acrylate ester copolymers, such as poly(ethylene-co-methyl acrylate) and poly(ethylene-co-butyl acrylate), ionomers, silicone polymers and epoxy resins. As used herein, the term “ionomer” means and denotes a thermoplastic resin containing both covalent and ionic bonds derived from ethylene/acrylic or methacrylic acid copolymers. In some embodiments, monomers formed by partial neutralization of ethylene-methacrylic acid copolymers or ethylene-acrylic acid copolymers with inorganic bases having cations of elements from Groups I, II, or III of the Periodic table, notably, sodium, zinc, aluminum, lithium, magnesium, and barium may be used. The term ionomer and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical 30 Properties And Structural Features Of Surlyn ionomer Resins”, Polyelectrolytes, 1976, C, 177-197. Other suitable ionomers are further described in European patent no. EP1781735. The front encapsulant layer may further contain any additive known within the art. Such exemplary additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, reinforcement additives such as glass fiber, fillers and the like. The front encapsulant layer typically has a thickness greater than or equal to 0.12 mm, and preferably greater than 0.25 mm. A preferred front encapsulant layer has a thickness in the range of 0.5 to 0.8 mm.

The photovoltaic module may further comprise one or more front sheet layers or film layers to serve as the light-transmitting substrate (also know as the incident layer). The light-transmitting layer may be comprised of glass or plastic sheets, such as, polycarbonate, acrylics, polyacrylate, cyclic polyolefins, such as ethylene norbornene polymers, metallocene-catalyzed polystyrene, polyamides, polyesters, fluoropolymers and the like and combinations thereof. Glass most commonly serves as the front sheet incident layer of the photovoltaic module. The term “glass” is meant to include not only window glass, plate glass, silicate glass, sheet glass, low iron glass, tempered glass, tempered CeO-free glass, and float glass, but also includes colored glass, specialty glass which includes ingredients to control, for example, solar heating, coated glass with, for example, sputtered metals, such as silver or indium tin oxide, for solar control purposes, E-glass, Toroglass, Solex® glass (a product of Solutia) and the like. The type of glass depends on the intended use.

A process of manufacturing the photovoltaic module with fluoropolymer/EPDM containing backsheet will now be disclosed. The photovoltaic module may be produced through a vacuum lamination process. For example, the photovoltaic module constructs described above may be laid up in a vacuum lamination press and laminated together under vacuum with heat and standard atmospheric or elevated pressure. In an exemplary process, a glass sheet, a front-sheet encapsulant layer, a photovoltaic cell layer, and an EPDM-containing layer adhered to a fluoropolymer film are laminated together under heat and pressure and a vacuum to remove air. Preferably, the glass sheet has been washed and dried. In an exemplary procedure, the laminate assembly of the present invention is placed onto a platen of a vacuum laminator that has been heated to about 120° C. The laminator is closed and sealed and a vacuum is drawn in the chamber containing the laminate assembly. After an evacuation period of about 6 minutes, a silicon bladder is lowered over the laminate assembly to apply a positive pressure of about 1 atmosphere over a period of 1 to 2 minutes. The pressure is held for about 14 minutes, after which the pressure is released, the chamber is opened, and the laminate is removed from the chamber.

If desired, the edges of the photovoltaic module may be sealed to reduce moisture and air intrusion by any means known within the art. Such moisture and air intrusion may degrade the efficiency and lifetime of the photovoltaic module. General art edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

The described process should not be considered limiting. Essentially, any lamination process known within the art may be used to produce the photovoltaic modules with an integrated back-sheet of an EPDM-containing layer adhered to a fluoropolymer film, as disclosed herein.

While the presently disclosed invention has been illustrated and described with reference to preferred embodiments thereof, it will be appreciated by those skilled in the art that various changes and modifications can be made without departing from the scope of the present invention as defined in the appended claims.

### EXAMPLES

The following Examples are intended to be illustrative of the present invention, and are not intended in any way to limit the scope of the present invention described in the claims.

### Test Methods

### Damp Heat Exposure

The samples are placed into a dark chamber. The samples are mounted at approximately a 45 degree angle to the horizontal. The chamber is then brought to a temperature of 85° C. and relative humidity of 85%. These conditions are maintained for a specified number of hours. Samples are removed and tested after about 1000 hours or 3000 hours of exposure. 1000 hours of exposure at 85° C. and 85% relative humidity is the required exposure in many photovoltaic module qualification standards.

### Peel Strength

After the designated number of hours of damp heat exposure in the heat and humidity chamber, the laminated samples were removed for peel strength testing. Peel strength is a measure of adhesion between layers of the laminate. The peel strength was measured on an Instron mechanical tester with a 50 kilo loading cell using ASTM D3167.

### Preparation of Test Sample EPDM Substrate Slabs

The ingredients listed in Table 1 were mixed in a tangential BR Banbury internal mixer made by Farrel Corporation of Ansonia, Conn. The non-polymer additives were charged into the mixing chamber of the Banbury mixer and mixed before the ethylene propylene diene terpolymer (EPDM) and any thermoplastic polymer adhesive or rosin tackifier ingredients were introduced into the mixing chamber, in what is known as an upside down mixing procedure. The ingredient quantities listed in Table 1 are by weight parts relative to the parts EPDM and other ingredients used in each of the examples.

The speed of the Banbury mixer's rotor was set to 75 rpm and cooling water at tap water temperature was circulated through a cooling jacket around the mixing chamber and through cooling passages in the rotor. The cooling water was circulated to control the heat generated by the mixing. The temperature of the mass being compounded was monitored during mixing. After all of the ingredients were charged into the mixing chamber and the temperature of the mass reached 82° C., a sweep of the mixing chamber was done to make sure that all ingredients were fully mixed into the compounded mass. When the temperature of the compounded mass reached 120° C., it was dumped from the mixing chamber into a metal mold pan.

The compounded mass in the mold pan was then sheeted by feeding the mixture into a 16 inch two roll rubber mill. Mixing of the compound was finished on the rubber mill by cross-cutting and cigar rolling the compounded mass. During sheeting, the mass cooled.

Sample slabs were prepared by re-sheeting the fully compounded mass on a two roll rubber mill in which the rolls were heated to 80° C. The compound was run between the rolls from five to ten times in order to produce a 30 mil (0.76 mm) thick sheet with smooth surfaces. Six inch by six inch (15.2 cm by 15.2 cm) pre-form squares were die cut from the sheet. A number of the pre-forms were put in a compression mold heated to 100° C., and the mold was put into a mechanical press and subjected to pressure. The mold pressure was initially applied and then quickly released and reapplied two times in what is known as bumping the mold, after which the mold pressure was held for 5 minutes. Cooling water was introduced into the press platens in order to reduce the mold temperature. When the mold cooled to 35° C., the press was opened and the sample substrate slabs were removed.

TABLE 1

| | Slab Sample No. | | | | | | |
|---|---|---|---|---|---|---|---|
| | 1 | 2 | 3 | 4 | 5 | 6 | 7 |
| EPDM (Nordel | 100 | 100 | | 100 | 100 | 100 | 100 |
| 3640) | | | | | | | |
| EPDM (Nordel | | | 100 | | | | |
| 5565) | | | | | | | |
| Hot Melt Polymer | | | | 50 | | | |
| Adhesive | | | | | | | |
| Hydrogenated Rosin | | | | | 50 | | |
| A Tackifier | | | | | | | |
| Ethylene-Methyl | | | | | | 50 | |
| Acrylate Copolymer | | | | | | | |
| Hydrogenated Rosin | | | | | | | 50 |
| B Tackifier | | | | | | | |
| Dixie Clay | 70 | 70 | 70 | 70 | 70 | 70 | 70 |
| Hi-Sil 233 | 20 | 20 | 20 | 20 | 20 | 20 | 20 |
| Ti-pure R-960 | 10 | 10 | 10 | 10 | 10 | 10 | 10 |
| Zinc Oxide | 5 | 5 | 5 | 5 | 5 | 5 | 5 |
| Stearic Acid | 1.5 | 1.5 | 1.5 | 1.5 | 1.5 | 1.5 | 1.5 |
| Carbowax 3350 | 1.5 | 1.5 | 1.5 | 1.5 | 1.5 | 1.5 | 1.5 |
| Winstay L | 2 | 2 | 2 | 2 | 2 | 2 | 2 |
| Sunpar 150 | 10 | 10 | 10 | 10 | 10 | 10 | 10 |
| Ultramarine Blue | 0.2 | 0.2 | 0.2 | 0.2 | 0.2 | 0.2 | 0.2 |
| Z-6030 Silane | 2 | | | | | | |
| Varox DBPH | 5 | | | | | | |
| SR 634 | 4 | | | | | | |
| Total Parts | 231.2 | 220.2 | 220.2 | 270.2 | 270.2 | 270.2 | 270.2 |

### Ingredient Glossary

| | |
|---|---|
| EPDM (Nordel 3640) | Ethylene-propylene-ethylidenenorbornene |
| | terpolymer, Dow Chemical Company, Midland, |
| | Michigan, USA |
| EPDM (Nordel 5565) | Ethylene-propylene-ethylidenenorbornene |
| | terpolymer, Dow Chemical Company, Midland, |
| | Michigan, USA |
| Hot Melt Polymer | Euromelt 707 US synthetic hot melt polymer |
| Adhesive | adhesive from Henkel Corporation of |
| | Dusseldorf, Germany |
| Hydrogenated Rosin A | FloraRez 485 glycerol ester hydrogenated rosin |
| Tackifier | tackifier from Florachem Corporation, |
| | Jacksonville, Florida, USA |
| Ethylene-Methyl | Bynel ® 22E757 ethylene-methyl acrylate |
| Acrylate Copolymer | copolymer thermoplastic resin from E. I. DuPont |
| | de Nemours and Company, Wilmington, |
| | Delaware, USA |
| Hydrogenated Rosin B | Stabelite Ester-E hydrogenated rosin-based |
| Tackifier | tackifier from Eastman Chemical of Kingsport, |
| | Tennessee, USA |
| Dixie Clay | Hydrated aluminum silicate mineral, R.T. |
| | Vanderbilt Company, Norwalk, Connecticut, |
| | USA |
| Hi-Sil 233 | Hydrated amorphous silica, PPG Industries, Inc., |
| | Pittsburgh, Pennsylvania, USA |
| Ti-pure R-960 | TiPure ® R-960 titanium dioxide from DuPont |
| Zinc Oxide | Zinc oxide, Horsehead Co., Monaca, |
| | Pennsylvania, USA |
| Stearic Acid | Stearic acid, PMC Biogenix Inc., Memphis, |
| | Tennessee, USA |
| Carbowax 3350 | Carbowax polyethylene glycol 3350 plasticizer |
| | from Dow Chemical Company of Midland, |
| | Michigan, USA |
| Winstay L | Phenol, 4-methyl-, reaction products with |
| | dicyclopentadiene and isobutylene. |
| | Butylated reaction product of p-cresol and |
| | dicyclopentadiene, OMNOVA Solutions Inc., |
| | Akron, Ohio, USA |
| Sunpar 150 | Paraffinic petroleum oil, Sunoco, Philadelphia, |
| | Pennsylvania, USA |
| Ultramarine Blue | Sodium aluminum sulphosilicate, Akrochem Co., |
| | Akron, Ohio, USA |
| Z-6030 Silane | Methacryloxypropyl trimethoxysilane, Dow |
| | Corning Inc., Midland, Michigan, USA |
| Varox DBPH | 2,5-dimethyl-2,5-di(t-butylperoxy)hexane, |
| | R.T. Vanderbilt Company, Inc., Norwalk, |
| | Connecticut, USA |
| SR 634 | Metallic dimethacrylate, Sartomer Company, |
| | Inc., Exton, Pennsylvania, USA |

### Preparation and Testing of Back-Sheet Substrate Samples

Back-sheet substrate laminated samples were made using at least two sample substrates for each of the slab nos. 1 to 7 of Table 1 above. The lamination was accomplished by preparing a layered structure having PTFE based heat bumper, followed by a 5 mil (0.13 mm) thick cell support release sheet made of Teflon® PTFE, followed by a 1.5 mil (0.38 mm) thick Tedlar® PVF film, followed by the 30 mil (0.76 mm) thick single layer sample slab from Table 1, and then followed by a 5 mil (0.13 mm) thick cell support release sheet made of Teflon® PTFE. The sample slabs of Table 1 were cut to approximately 6 inches long and approximately 6 inch wide so as to have a similar length and width as the mono-crystalline silicon solar cell.

The layered structure was placed into a lamination press having a platen heated to about 130° C. The layered structure was allowed to rest on the platen for about 6 minutes to preheat the layered structure under vacuum. The lamination press was activated and the layered structure was pressed together using 1 atmosphere of pressure for 14 minutes.

The back-sheet substrate laminated samples were tested for initial peel strength and were subsequently subjected to the damp heat exposure test described above for 1000 hours and then tested again for peel strength between the EPDM containing substrate and the PVF film.

As show below in Table 2, the back-sheet substrate laminate samples had very high peel strength between the EPDM containing substrate layer and Tedlar® PVF film both before and after 1000 hours of damp heat exposure. During initial peel strength testing and post damp heat peel strength testing, the EPDM sample slabs could not be separated from the Tedlar® PVF film. The PVF film tore before there was separation in the bond between the EPDM slab and the PVF film.

TABLE 2

| | Example | | | | | | |
|---|---|---|---|---|---|---|---|
| | 1 | 2 | 3 | 4 | 5 | 6 | 7 |
| | Slab Sample No. | | | | | | |
| | 1 | 2 | 3 | 4 | 5 | 6 | 7 |
| Initial Peel Strength | CNS | CNS | CNS | CNS | CNS | CNS | CNS |
| (g/in) | | | | | | | |
| Peel Strength after | CNS | CNS | CNS | CNS | CNS | CNS | CNS |
| 1000 hours of Damp | | | | | | | |
| and Heat (g/in) | | | | | | | |

CNS = could not separate EPDM slab from PVF film before tearing occurred in the PVF film.

### Preparation and Testing of Mini Solar Modules

Mini solar modules were prepared from a layered structure of a 5 mm thick glass sheet, followed by an 18 mil (0.46 mm) thick ionomer encapsulant layer, followed by a mono-crystalline silicon solar cell with a back side contact made of aluminum and iso butyl rubber edge seals, followed the 0.76 mm thick EPDM-containing slab of Table 1, followed by a 1.5 mil (0.38 mm) thick Tedlar® PVF film, followed by a 5 mil thick cell support release sheet made of Teflon® PTFE, followed by a PTFE based heat bumper. The cell had electrical connects to the outside at desired locations.

The layered structure was placed into a lamination press having a platen heated to about 120-150° C. The layered structure was allowed to rest on the platen for about 6 minutes to preheat the layered structure under vacuum. The lamination press was activated and the layered structure was pressed together using 1 atmosphere of pressure for 14 minutes to permit the sample slab and front encapsulant to encapsulate silicon solar cell. The mini solar module was cooled and removed from the press.

The mini modules were tested for electrical current leakage under wet conditions prior to exposure to damp heat, after 1000 hours of damp heat exposure as described above. The wet leakage current test was conducted according to Section 10.15 of IEC 61215. According to the test, the mini modules are immersed in a water bath and tested for insulation resistance. The water bath temperature was 22° C. For the tested mini module construction, the insulation resistance must be greater than 1.7 GO to pass. In Table 3 below, resistance of >10 GO means that current was too low to measure. Maximum power (Pmax), short circuit current (Isc), open circuit voltage (Voc), series resistance (Rs), shunt resistance (Rsh), and wet leakage resistivity were determined using a Spire SLP 4600 solar simulator. Prior to any testing, the instrument was calibrated using an NREL certified solar module (Kyocera 87 watt module). The thermal coefficient for 5″ JA Solar cells was used. The following standard conditions for single cell 5 inch modules were used:

Lamp intensity=100 mW/cm²

Fixed starting load voltage=7.2 V

Fixed voltage range=25 V

Fixed current range=6 A

TABLE 3

| | Example | | | | | |
|---|---|---|---|---|---|---|
| | 8 | 9 | 10 | 11 | 12 | 13 |
| | Slab Sample No. | | | | | |
| | 1 | 2 | 4 | 5 | 6 | 7 |
| Pₘₐₓ (W) (initial) | 2.326 | 2.412 | 2.373 | 2.386 | 2.411 | 2.387 |
| Pₘₐₓ (W) (1000 hrs DH) | 2.444 | 2.449 | 2.439 | 2.449 | 2.434 | 2.443 |
| Pₘₐₓ (W) (2000 hrs DH) | 2.451 | 2.471 | 2.449 | 2.458 | 2.456 | 2.452 |
| Pₘₐₓ (W) (3000 hrs DH) | 2.263 | 2.259 | 2.259 | 2.197 | 2.260 | 2.145 |
| Isc (A) (initial) | 5.350 | 5.334 | 5.325 | 5.351 | 5.359 | 5.351 |
| Isc (A) (1000 hrs DH) | 5.286 | 5.283 | 5.277 | 5.293 | 5.272 | 5.265 |
| Isc (A) (2000 hrs DH) | 5.308 | 5.333 | 5.312 | 5.341 | 5.327 | 5.338 |
| Isc (A) (3000 hrs DH) | 5.296 | 5.287 | 5.273 | 5.309 | 5.297 | 5.313 |
| Voc (V) (initial) | 0.598 | 0.611 | 0.606 | 0.607 | 0.611 | 0.610 |
| Voc (V) (1000 hrs DH) | 0.625 | 0.624 | 0.625 | 0.624 | 0.625 | 0.627 |
| Voc (V) (2000 hrs DH) | 0.623 | 0.623 | 0.623 | 0.625 | 0.624 | 0.624 |
| Voc (V) (3000 hrs DH) | 0.623 | 0.623 | 0.623 | 0.623 | 0.623 | 0.624 |
| Rs (Ω) (initial) | 0.012 | 0.012 | 0.011 | 0.011 | 0.010 | 0.012 |
| Rs (Ω) (1000 hrs DH) | 0.011 | 0.010 | 0.012 | 0.011 | 0.012 | 0.011 |
| Rs (Ω) (2000 hrs DH) | 0.010 | 0.010 | 0.010 | 0.013 | 0.009 | 0.010 |
| Rs (Ω) (3000 hrs DH) | 0.016 | 0.019 | 0.018 | 0.018 | 0.019 | 0.020 |
| Rsh (Ω) (initial) | 35.412 | 31.821 | 36.093 | 35.221 | 32.277 | 34.477 |
| Rsh (Ω) (1000 hrs DH) | 34.049 | 38.716 | 36.023 | 34.749 | 42.221 | 38.128 |
| Rsh (Ω) (2000 hrs DH) | 31.594 | 32.008 | 34.460 | 29.913 | 33.454 | 33.246 |
| Rsh (Ω) (3000 hrs DH) | 30.352 | 33.635 | 38.209 | 30.886 | 30.923 | 42.979 |
| Resistivity (GΩ) (initial) | >10 | >10 | >10 | >10 | >10 | >10 |
| Resistivity (GΩ) | >10 | >10 | >10 | >10 | >10 | >10 |
| (1000 hrs DH) | | | | | | |

What is claimed is:

1. A process for forming a back-sheet for a photovoltaic module, comprising:
providing a fluoropolymer film;
providing a polymer melt comprising 20 to 95 weight percent ethylene propylene diene terpolymer, 5 to 70 weight percent of inorganic particulates, and 0 to 50 weight percent of adhesive selected from thermoplastic polymer adhesives and tackifiers, based on the weight of the polymer melt;
depositing the polymer melt directly on the fluoropolymer film and pressing said fluoropolymer film and polymer melt together and cooling the polymer melt to form a first polymer layer from the polymer melt, the first polymer layer having a thickness of at least 0.1 mm, wherein the peel strength between said fluoropolymer film and said first polymer layer is greater than 2 Newtons/cm after 1000 hours of exposure at 85° C. and 85% relative humidity.

2. The process of claim 1 wherein said first polymer layer comprises 25 to 90 weight percent ethylene propylene diene terpolymer, 5 to 70 weight percent of inorganic particulates, and 5 to 35 weight percent of adhesive selected from thermoplastic polymer adhesives and rosin based tackifiers, based on the weight of the first polymer layer.

3. The process of claim 1 wherein said first polymer layer comprises 10 to 70 weight percent of inorganic particulates selected from silica and silicates and having an average particle diameter between and including any two of the following diameters: 0.1, 0.2, 15, 45, and 100 microns.

4. The process of claim 1 wherein said polymer melt is deposited on the fluoropolymer film by extruding the polymer melt as a layer directly onto the fluoropolymer film.

5. The process of claim 1 wherein said polymer melt is formed between heated calendar rolls and wherein said polymer melt is deposited from said heated calendar rolls onto said fluoropolymer film and passed through a nip to form a polymer layer adhered to said fluoropolymer film, said polymer layer having a thickness of at least 0.25 mm.

6. The process of claim 1 wherein the peel strength between said fluoropolymer film and said first polymer layer is greater than 8 Newtons/cm after 1000 hours of exposure at 85° C. and 85% relative humidity.

7. A process for forming a photovoltaic module, comprising:
providing a fluoropolymer film;
providing a polymer melt comprising 20 to 95 weight percent ethylene propylene diene terpolymer, 5 to 70 weight percent of inorganic particulates, and 0 to 50 weight percent of adhesive selected from thermoplastic polymer adhesives and tackifiers, based on the weight of the polymer melt;
depositing the polymer melt directly on the fluoropolymer film and pressing said fluoropolymer film and polymer melt together to form a first polymer layer from the polymer melt, the first polymer layer having a thickness of at least 0.1 mm and first and second opposite sides, wherein the first side of the polymer layer adheres directly to the fluoropolymer film with a peel strength greater than 2 Newtons/cm after 1000 hours of exposure at 85° C. and 85% relative humidity;
providing a plurality of solar cells each having a front sunlight receiving side and an opposite rear side; and
pressing the second side of said first polymer layer directly against the rear side of said solar cells and heating said first polymer layer to adhere the second side of the first polymer layer to the rear side of said solar cells.

8. The process of claim 7 wherein said first polymer layer comprises 25 to 90 weight percent ethylene propylene diene terpolymer, 5 to 70 weight percent of inorganic particulates, and 5 to 35 weight percent of adhesive selected from thermoplastic polymer adhesives and rosin based tackifiers, based on the weight of the first polymer layer.

9. The process of claim 7 wherein said first polymer layer comprises 10 to 70 weight percent of inorganic particulates, based on the weight of the first polymer layer, and wherein the inorganic particulates are selected from silica and silicates having an average particle diameter between and including any two of the following diameters: 0.1, 0.2, 15, and 45 microns.

10. The process of claim 7 wherein said polymer melt is deposited on the fluoropolymer film by extruding the polymer melt as a layer directly onto the fluoropolymer film.

11. A photovoltaic module comprising:
a plurality of solar cells having a front light receiving side and an opposite rear side;
a polymer layer having opposite first and second sides, the first side of the polymer layer being adhered directly to the rear side of said plurality of solar cells, said polymer layer comprising 20 to 95 weight percent ethylene propylene diene terpolymer, 5 to 70 weight percent of inorganic particulates, and 0 to 50 weight percent of adhesive selected from thermoplastic polymer adhesives and tackifiers, based on the weight of the polymer layer;
a fluoropolymer film adhered directly to the second side of the polymer layer.

12. The photovoltaic module of claim 11 wherein said polymer layer comprises 25 to 90 weight percent ethylene propylene diene terpolymer, 5 to 70 weight percent of inorganic particulates, and 5 to 35 weight percent of adhesive selected from thermoplastic polymer adhesives and rosin based tackifiers, based on the weight of the polymer layer.

13. The photovoltaic module of claim 11 wherein said polymer layer comprises 10 to 70 weight percent of inorganic particulates based on the weight of the polymer layer, said organic particulates selected from silica and silicates and having an average particle diameter between and including any two of the following diameters: 0.2, 15, and 45 microns.

14. The photovoltaic module of claim 11 wherein said polymer layer comprises 10 to 70 weight percent of inorganic particulates based on the weight of the polymer layer, and said organic particulates are selected from silica and silicates and having an average particle diameter in the range of 0.2 to 20 microns.

15. The photovoltaic module of claim 11 wherein said inorganic particulates are selected from the group of calcium carbonate, titanium dioxide, kaolin and clays, alumina trihydrate, talc, silica, antimony oxide, magnesium hydroxide, barium sulfate, mica, vermiculite, alumina, titania, wollastinite, boron nitride, and combinations thereof.

16. The photovoltaic module of claim 11 wherein said polymer layer has a thickness in the range of 0.25 to 0.80 mm, and the peel strength between said fluoropolymer film and said first polymer layer is greater than 8 Newtons/cm after 1000 hours of exposure at 85° C. and 85% relative humidity.

17. The photovoltaic module of claim 11 wherein said fluoropolymer film is a film comprised of fluoropolymers selected from polyvinylfluoride, polyvinylidene fluoride, polytetrafluoroethylene, ethylene-tetrafluoroethylene copolymer and combinations thereof.

18. The photovoltaic module of claim 11 wherein said polymer layer further comprises a metal layer from the group of metal foils, sputtered metal layers, and metal oxide layers.

19. The photovoltaic module of claim 11 wherein the adhesive of said polymer layer comprises one or more rosin based tackifiers.

20. The photovoltaic module of claim 11 wherein the adhesive of said polymer layer comprises a non-aromatic copolymer comprised of ethylene units copolymerized with one or more of the monomer units selected from C₃₋₂₀ alpha olefins, C₁₋₄ alkyl methacrylates, C₁₋₄ alkyl acrylates, methacrylic acid, acrylic acid, maleic anhydride, and glycidyl methacrylate, wherein the adhesive copolymer is comprised of at least 50 wt % ethylene derived units, and blends thereof in any ratio.
